(19) United States
(12) Patent Application Publication
(10) Pub. No.: US 2014/0284694 A1
(43) Pub. Date: Sep. 25, 2014

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventors: Soichirou Kitazaki, Mie-Ken (JP); Mitsuru Sato, Mie-ken (JP)

(73) Assignee: Kabushiki Kaisha Toshiba, Minato-ku (JP)

(21) Appl. No.: 14/020,254

(22) Filed: Sep. 6, 2013

Related U.S. Application Data
(60) Provisional application No. 61/803,496, filed on Mar. 20, 2013.

(51) Int. Cl. H01L 29/792; H01L 29/66

(52) U.S. Cl. CPC H01L 29/792; H01L 29/66833
USPC 257/324; 438/287

(57) ABSTRACT

According to one embodiment, a nonvolatile semiconductor memory device includes: a stacked body, each of a plurality of electrode layers and each of a plurality of insulating layers being stacked alternately in the stacked body; an interlayer insulating film provided on the stacked body; a gate electrode provided on the interlayer insulating film; a semiconductor layer extending from an upper end of the gate electrode to a lower face of the stacked body; a first insulating film provided between the semiconductor layer and each of the plurality of electrode layers and including at least one layer of a nitride film; and a second insulating film provided between the gate electrode and the semiconductor layer and including at least one layer of a nitride film, a film thickness of at least a part of the second insulating film being thinner than a film thickness of the first insulating film.

### CROSS-REFERENCE TO RELATED APPLICATIONS

This application is based upon and claims the benefit of priority from U.S. Provisional Patent Application 61/803,496, filed on Mar. 20, 2013; the entire contents of which are incorporated herein by reference.

### FIELD

Embodiments described herein relate generally to a nonvolatile semiconductor memory device and a method for manufacturing same.

### BACKGROUND

Recently, in the field of memory devices, attention is focused on a three-dimensional memory cell structure in which a memory hole is formed in a stacked body in which a plurality of electrode layer serving as a control gate are stacked, a memory film is formed on the side wall of this memory hole, and further a channel body layer is formed inside the memory film. This kind of three-dimensional memory cell structure has a memory string structure including the channel body layer extending in the stacking direction of the stacked body.

In a formation process of the memory string structure, the memory film is formed also on the side wall of a selection gate electrode in addition to the side wall of the electrode layer. However, the memory film is designed so as to obtain better charge holding characteristics. Accordingly, when an insulating film is formed on the side face of the selection gate electrode having the same structure as the memory film, there arises a problem in which controllability of the selection gate electrode is not enhanced.

### BRIEF DESCRIPTION OF THE DRAWINGS

FIG. 1 is a schematic perspective view for a memory cell array of the nonvolatile semiconductor memory device according to a first embodiment;

FIGS. 2A to 2C are schematic cross-sectional views of the nonvolatile semiconductor memory device according to the first embodiment;

FIGS. 3A to 3D are schematic cross-sectional views describing a manufacturing process of the nonvolatile semiconductor memory device according to the first embodiment;

FIGS. 4A to 4C are schematic cross-sectional views describing a manufacturing process of the nonvolatile semiconductor memory device according to the first embodiment;

FIGS. 5A to 5B are schematic cross-sectional views describing a manufacturing process of the nonvolatile semiconductor memory device according to the first embodiment;

FIGS. 6A to 6C are schematic cross-sectional views describing the manufacturing process for a memory film and a gate insulating film according to the first embodiment;

FIGS. 7A to 7C are schematic cross-sectional views describing the manufacturing process for the memory film and the gate insulating film according to the first embodiment;

FIGS. 8A to 8C are schematic cross-sectional views describing the manufacturing process for the memory film and the gate insulating film according to the first embodiment;

FIGS. 9A to 9C are schematic cross-sectional views describing the manufacturing process for the memory film and the gate insulating film according to the first embodiment;

FIGS. 10A to 10C are schematic cross-sectional views describing the manufacturing process for the memory film and the gate insulating film according to the first embodiment;

FIGS. 11A to 11C are schematic cross-sectional views describing the manufacturing process for the memory film and the gate insulating film according to the first embodiment;

FIGS. 12A to 12C are schematic cross-sectional views explaining the manufacturing process for the nonvolatile semiconductor memory device according to the first embodiment;

FIGS. 13A and 13B are schematic cross-sectional views of a nonvolatile semiconductor memory device according to a second embodiment, and FIG. 13A is a schematic cross-sectional view in the vicinity of the electrode layer and FIG. 13B is a schematic cross-sectional view in the vicinity of the selection gate;

FIG. 14A is a schematic cross-sectional view in the vicinity of the selection gate electrode in a nonvolatile semiconductor memory device according to a third embodiment, FIG. 14B is a schematic cross-sectional view in the vicinity of the electrode layer in the nonvolatile semiconductor memory device according to the third embodiment, and FIG. 14C is a schematic cross-sectional view in the vicinity of the selection gate electrode in the nonvolatile semiconductor memory device according to the first embodiment; and

FIG. 15A is a schematic plan view in the vicinity of the selection gate electrode in the nonvolatile semiconductor memory device according to a third embodiment, FIG. 15B is a schematic plan view in the vicinity of the electrode layer in the nonvolatile semiconductor memory device according to the third embodiment, and FIG. 15C is a schematic plan view in the vicinity of the selection gate electrode in the nonvolatile semiconductor memory device according to the first embodiment.

### DETAILED DESCRIPTION

In general, according to one embodiment, a nonvolatile semiconductor memory device includes: a foundation layer; a stacked body provided on the foundation layer, each of a plurality of electrode layers and each of a plurality of insulating layers being stacked alternately in the stacked body; an interlayer insulating film provided on the stacked body; a gate electrode provided on the interlayer insulating film; a semiconductor layer extending from an upper end of the gate electrode to a lower face of the stacked body; a first insulating film provided between the semiconductor layer and each of the plurality of electrode layers, and the first insulating film including at least one layer of a nitride film; and a second insulating film provided between the gate electrode and the semiconductor layer, and the second insulating film including at least one layer of a nitride film, a film thickness of at least a part of the second insulating film being thinner than a film thickness of the first insulating film.

Embodiments will now be described below with reference to the drawings. In the following description, like member are identified with like numerals, and the description of members described once will be omitted as appropriate.

### First Embodiment

Hereinafter, an embodiment will now be described with reference to the drawings. In the following description, like member are identified with like numerals, and the description of members described once will be omitted as appropriate.

First, an outline of a structure for a nonvolatile semiconductor memory device 1 will be described according to a first embodiment.

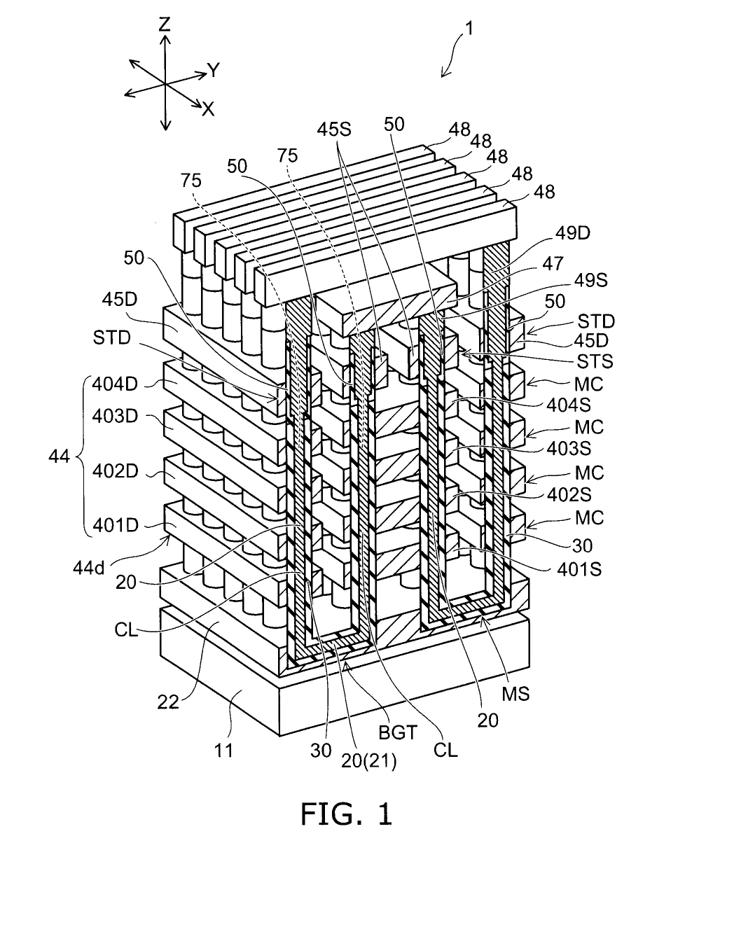

FIG. 1 is a schematic perspective view for a memory cell array of the nonvolatile semiconductor memory device according to the first embodiment. In FIG. 1, illustration of an insulating part except an insulating film formed on the inner wall of a memory hole 75 is omitted.

In FIG. 1, an XYZ orthogonal coordinate system is introduced for convenience of explanation. In this coordinate system, two directions which are parallel to the major surface of a foundation layer 11 and perpendicular to each other are defined as an X-direction and a Y-direction, and a direction perpendicular to these X-direction and Y-direction is defined as a Z-direction.

The nonvolatile semiconductor memory device 1 according to the first embodiment is a nonvolatile semiconductor storage device which can freely perform data erasing and writing electrically and can retain stored contents even when power is shut down.

In the nonvolatile semiconductor memory device 1, a semiconductor layer 22 (back gate layer) is provided on the foundation layer 11 via an insulating layer which is not shown in the drawing. The foundation layer 11 includes a semiconductor substrate, an insulating layer, a circuit, and the like. For example, in the foundation layer 11, there are provided an active element such as a transistor and a passive element such as a resistor and a capacitor. The semiconductor layer 22 is a silicon (Si) layer to which an impurity element such as, for example, boron (B) is added.

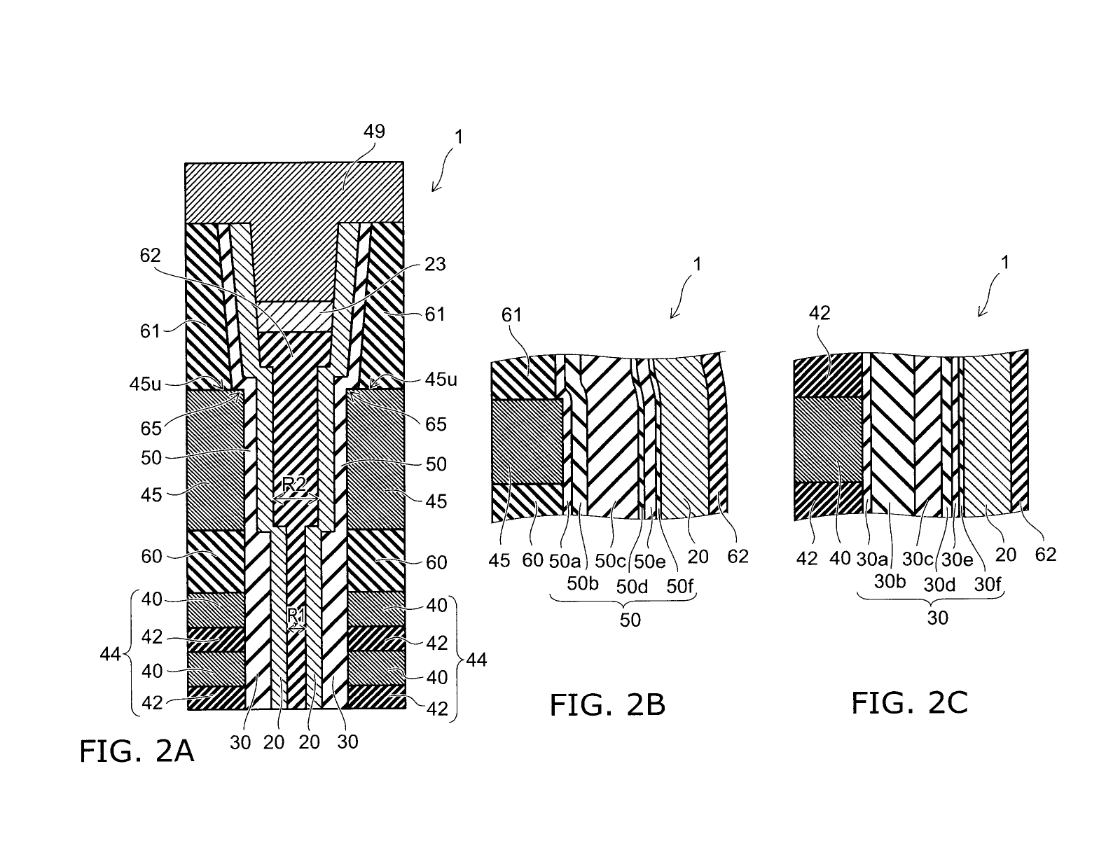

Drain-side electrode layers 401D, 402D, 403D, and 404D and source-side electrode layers 401S, 402S, 403S, and 404S are stacked on the semiconductor layer 22. In the Z-direction, insulating layers 42 (first insulating layer) are provided between these electrodes (not shown in FIG. 1 and refer to FIGS. 2A to 2C). The material of the insulating layer 42 contains, for example, silicon oxide (SiO₂).

The electrode layer 401D and the electrode layer 401S are provided in the same level layer and indicate the first electrode layer from the bottom. The electrode layer 402D and the electrode layer 402S are provided in the same level layer and indicate the second electrode layer from the bottom. The electrode layer 403D and the electrode layer 403S are provided in the same level layer and indicate the third electrode layer from the bottom. The electrode layer 404D and the electrode layer 404S are provided in the same level layer and indicate the fourth electrode layer from the bottom.

The electrode layer 401D and the electrode layer 401S are separated from each other in the Y-direction. The electrode layer 402D and the electrode layer 402S are separated from each other in the Y-direction. The electrode layer 403D and the electrode layer 403S are separated from each other in the Y-direction. The electrode layer 404D and the electrode layer 404S are separated from each other in the Y-direction.

Insulating layers which are not shown in the drawing are provided between the electrode layer 401D and the electrode layer 401S, between the electrode layer 402D and the electrode layer 402S, between the electrode layer 403D and the electrode layer 403S, and between the electrode layer 404D and the electrode layer 404S.

The electrode layers 401D, 402D, 403D and 404D are provided between the semiconductor layer 22 and a drain-side selection gate electrode 45D. The electrode layers 401S, 402S, 403S, and 404S are provided between the semiconductor layer 22 and a source-side selection gate electrode 45S.

In the following description, the electrode layers 401D, 402D, 403D, 404D, 401S, 402S, 403S, and 404S are simply expressed as an electrode layer 40 as a whole. Furthermore, the number of layers for the electrode layer 40 is arbitrary and is not limited to the four layers illustrated in the first embodiment. Moreover, a stacked body 44 is configured including the electrode layer 40 and the insulating layer 42. The lower face of the first electrode layer 401 (or electrode layer 401S) comes to be the lower face 44d of the stacked body 44. The electrode layer 40 is a conductive silicon layer to which an impurity element such as, for example, boron (B) is added.

The drain-side selection gate electrode 45D is provided on the electrode layer 404D via an insulating layer which is not shown in the drawing. The drain-side selection gate electrode 45D is a conductive silicon layer to which an impurity such as, for example, boron (B) is added.

The source-side selection gate electrode 45S is provided on the electrode layer 404S via an insulating layer which is not shown in the drawing. The source-side selection gate electrode 45S is, for example, a conductive silicon layer to which an impurity is added.

The drain-side selection gate electrode 45D and the source-side selection gate electrode 45S are separated from each other in the Y-direction. The drain-side selection gate electrode 45D and the source-side selection gate electrode 45S are not distinguished from each other and are simply expressed also as selection gate electrodes 45 or gate electrodes 45.

A source line 47 is provided on the source-side selection gate electrode 45S via an insulating layer which is not shown in the drawing. The source line 47 is connected to one end in each of a pair of channel body layers 20 (semiconductor layers) via a via 49S. The source line 47 is a metal interconnect or a conductive silicon layer to which an impurity is added.

A plurality of bit lines 48 are provided on the drain-side selection gate electrode 45D and the source line 47, via an insulating layer which is not shown in the drawing. The bit line 48 is, for example, a metal interconnect or a conductive silicon layer to which an impurity is added. The bit line 48 is connected to the other end in the pair of channel body layers 20, via a via 49D. The bit line 48 extends in the Y-direction. The via 49S and the via 49D are not distinguished and are simply described as vias 49. The material of the via 49 is, for example, tungsten (W).

A plurality of U-shaped memory holes 75 are provided in the semiconductor layer 22 and the stacked body 44. For example, in the electrode layers 401D to 404D and the drain-side selection gate electrode 45D, a hole is formed extending in the Z-direction therethrough. In the electrode layers 4015 to 404S and the source-side selection gate electrode 45S, a hole is formed extending in the Z-direction therethrough. A pair of the holes extending in the Z-direction are connected with each other via the semiconductor layer 22 and constitute the U-shaped memory hole 75. The embodiment includes a straight-type memory hole other than the U-shaped memory hole (to be described below).

The U-shaped channel body layer 20 is provided inside the memory hole 75. The channel body layer 20 is, for example, a silicon layer. A memory film 30 (first insulating film) is provided between the channel body layer 20 and the inner wall of the memory hole 75 (to be described below).

A gate insulating film 50 (second insulating film) is provided between the channel body layer 20 and the drain-side selection gate electrode 45D. A gate insulating film 50 is provided between the channel body layer 20 and the source-side selection gate electrode 45S.

The embodiment is not limited to a structure in which the memory hole 75 is filled completely with the channel body layer 20 and may include a structure in which the channel body layer 20 is formed so as to leave a hollow part in the memory hole 75 on the center axis side and an insulator is embedded in the inside hollow part.

The drain-side selection gate electrode 45D, the channel body layer 20, and the gate insulating film 50 therebetween constitute a drain-side selection transistor STD. The channel body layer 20 above the drain-side selection transistor STD is connected electrically to the bit line 48.

The source-side selection gate electrode 45S, the channel body layer 20, and the gate insulating film 50 therebetween constitute a source-side selection transistor STS. The channel body layer 20 above the source-side selection transistor STS is connected electrically to the source line 47.

The drain-side selection transistor STD and the source-side selection transistor STS are cylindrical transistors.

The semiconductor layer 22 and the channel body layer 20 and memory film 30 provided within the semiconductor layer 22 constitute a back gate layer transistor BGT.

Between the drain-side selection transistor STD and the back gate layer transistor BGT, a plurality of memory cells MC are provided using the electrode layers 404D to 401D as control gates. In the same manner, also between the back gate layer transistor BGT and the source-side selection transistor STS, a plurality of memory cells MC are provided using the electrode layer 401S to 404S as control gates.

These pluralities of memory cells MC, the drain-side selection transistor STD, the back gate layer transistor BGT, and the source-side selection transistor STS are connected in series through the channel body layer and constitute one U-shaped memory string MS.

One memory string MS has a pair of columnar parts CL, which extends in the stacking direction of the stacked body 44 including the plurality of electrode layers 40, and has the connection part 21 which connects the pair of columnar parts CL and is embedded in the semiconductor layer 22. These plurality of memory strings MS are arranged in the X-direction and the Y-direction, and thus a plurality of memory cells are provided three-dimensionally in the X-direction, Y-direction and Z-direction.

The plurality of memory strings MS are provided in a memory array region of the foundation layer 11. In the periphery, for example, of the memory array region in the foundation layer 11, a peripheral circuit controlling the memory cell array is provided.

FIGS. 2A to 2C are schematic cross-sectional views of the nonvolatile semiconductor memory device according to the first embodiment. FIG. 2A is a schematic cross-sectional view for a part of the memory cell, FIG. 2B is a schematic cross-sectional view in the vicinity of the selection gate, and FIG. 2C is a schematic cross-sectional view in the vicinity of the electrode layer.

As shown in FIG. 2A, in the nonvolatile semiconductor memory device 1, the stacked body 44 is provided on the above-described foundation layer 11 (not shown in FIG. 2A and refer to FIG. 1), in which each of the plurality of electrode layers 40 and each of the plurality of insulating layers 42 are stacked alternately.

An interlayer insulating film 60 is provided on the stacked body 44. The selection gate electrode 45 is provided on the interlayer insulating film 60. An interlayer insulating film 61 is provided on the selection gate electrode 45. At a position where the selection gate electrode 45 and the interlayer insulating film 61 make contact with each other, a step 65 exists between the selection gate electrode 45 and the interlayer insulating film 61.

The channel body layer 20 extends at least from the upper end 45u of the selection gate electrode 45 to the lower face 44d of the stacked body 44 (refer to FIG. 1). The channel body layer 20 has a columnar shape. The material of a conductive layer 23 is a conductive silicon layer to which an impurity element such as, for example, phosphor (P) is added. The via 49 is provided on the conductive layer 23. An insulating layer 62 is provided inside the channel body layer 20 as a core material. The conductive layer 23 is provided on the insulating layer 62. The conductive layer 23 makes contact with the channel body layer 20.

As shown in FIG. 2B, the gate insulating film 50 is provided between the gate electrode 45 and the channel body layer 20. The gate insulating film 50 has a multilayer structure. The gate insulating film 50 is provided also inside the interlayer insulating film 61 other than between the gate electrode 45 and the channel body layer 20.

The gate insulating film 50 includes at least one layer of a nitride film. For example, a nitride film 50a, an oxide film 50b, a nitride film 50c, an oxide film 50d, a nitride film 50e, and an oxide film 50f are arranged sequentially from the side of the gate electrode 45 to the side of the channel body layer 20. The nitride films 50a, 50c, and 50e are films including, for example, silicon nitride (Si₃N₄). The nitride films 50c and 50e may include oxygen. The oxide films 50b, 50d, and 50f are films each including at least one of silicon oxide (SiO₂) and aluminum oxide (Al₂O₃).

As shown in FIG. 2C, the memory film 30 is provided between the channel body layer 20 and each of the plurality of electrode layers 40. The memory film 30 has a multilayer structure. The memory film 30 is provided also between the channel body layer 20 and each of the plurality of insulating layers 42 other than between the channel body layer 20 and each of the plurality of electrode layers 40.

The memory film 30 includes at least one layer of a nitride film. For example, a nitride film 30a, an oxide film 30b, a nitride film 30c, an oxide film 30d, a nitride film 30e, and an oxide film 30f are arranged in order from the side of the electrode layer 40 to the channel body layer 20. The nitride films 30a, 30c, and 30e are films including silicon nitride (Si₃N₄), for example. The oxide films 30b, 30d, and 30f are films each including at least one of silicon oxide (SiO₂) and aluminum oxide (Al₂O₃).

The memory film 30 functions as a memory film of the nonvolatile semiconductor memory device 1. The memory film 30 has an ONO (Oxide-Nitride-Oxide) structure in which a nitride film is sandwiched by a pair of oxide films. For example, the nitride film 30c is sandwiched by the oxide film 30b and the oxide film 30d. The nitride film 30c functions as a data storage layer storing charge injected from the channel body layer 20.

The gate insulating film 50 and the memory film 30 are connected with each other at the boundary between the interlayer insulating film 60 and the selection gate electrode 45. In the embodiment, the insulating films including the gate insulating film 50 and the memory film 30 are simply referred to as an insulating layer (second insulating layer).

The channel body layer 20 functions as a channel in the transistor constituting the memory cell. The electrode layer 40 functions as a control gate.

Furthermore, in the nonvolatile semiconductor memory device 1, the impurity concentration of the channel body layer 20 above the above described step 65 is set to be higher than the impurity concentration of the channel body layer 20 below the step 65, in order to efficiently generate GIDL (Gate Induced Drain Leakage).

In this manner, the nonvolatile semiconductor memory device 1 is provided with the memory cell having the structure in which the periphery of the channel is surrounded by the control gate at a part where the channel body layer 20 and the electrode layer 40 intersect with each other.

In the nonvolatile semiconductor memory device 1, the film thickness of at least a part of the gate insulating film 50 is thinner than the film thickness of the memory film 30. For example, in FIGS. 2A to 2C, it is shown that the film thickness across the whole region of the gate insulating film 50 is thinner than the film thickness across the whole region of the memory film 30.

Here, the “film thickness” means a physical film thickness measured by a stylus-type step gauge, a cross-sectional image, or the like. In the embodiment, this “film thickness” can also be replaced by an “equivalent oxide film thickness”. The equivalent oxide film thickness is a film thickness obtained when the film thickness of an object film is converted into an equivalent oxide film thickness through the use of the physical film thickness of the object film, relative permittivity of the object film, and relative permittivity of silicon oxide (SiO₂). For example, when the relative permittivity of the object film is “ε_{f}”, the physical film thickness of the object film is “d_{f}”, and the relative permittivity of a silicon oxide film is “ε_{SiO2}”, the equivalent oxide film thickness D of the object film is expressed by following formula (I).

D=d_{f}×(ε_{SiO2}/ε_{f}) (1)

In the nonvolatile semiconductor memory device 1, the equivalent oxide film thickness in at least a part of the gate insulating film 50 is thinner than the equivalent oxide film film thickness of the memory film 30.

Furthermore, in the nonvolatile semiconductor memory device 1, the film thickness of at least one layer of the nitride film included in the gate insulating film 50 is thicker than the film thickness of at least one layer of the nitride film included in the memory film 30. For example, the film thickness of the nitride film 50c is thicker than the film thickness of the nitride film 30c. The film thickness of the nitride film 50e is thicker than the film thickness of the nitride film 30e.

A manufacturing process of the nonvolatile semiconductor memory device 1 will be described.

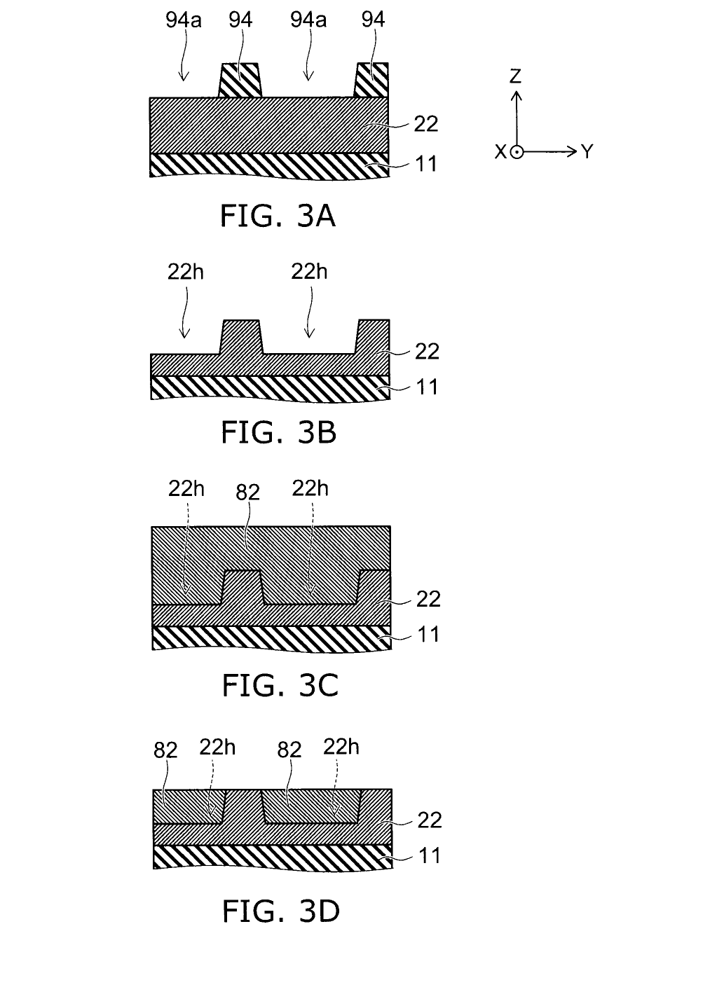

FIGS. 3A to 5B are schematic cross-sectional views describing a manufacturing process of the nonvolatile semiconductor memory device according to the first embodiment.

The film or layer formation method to be described below is selected arbitrarily from any of CVD (Chemical Vapor Deposition), a sputtering method, an ALD (Atomic Layer Deposition) method, an epitaxial method, a spin-coat method, and the like, if not specified in particular.

First, as shown in FIG. 3A, the semiconductor layer 22 is formed on the foundation layer 11. Successively, a resist pattern 94 is formed on the semiconductor layer 22. The resist pattern 94 has an opening 94a for opening a part of the surface of the semiconductor layer 22.

Next, as shown in FIG. 3B, the semiconductor layer 22 exposed from the resist pattern 94 is dry-etched through the use of the resist pattern 94 as a mask. Thereby, a concave part 22h is formed in the semiconductor layer 22.

Next, as shown in FIG. 3C, a sacrifice layer 82 is formed on the semiconductor layer 22. Thereby, the sacrifice layer 82 is formed in the concave part 22h. The material of the sacrifice layer 82 is, for example, a silicon nitride film, non-doped silicon, or the like. After that, the surface of the semiconductor layer 22 is exposed by etching-back of the surface of the sacrifice layer 82. This state is shown in FIG. 3D.

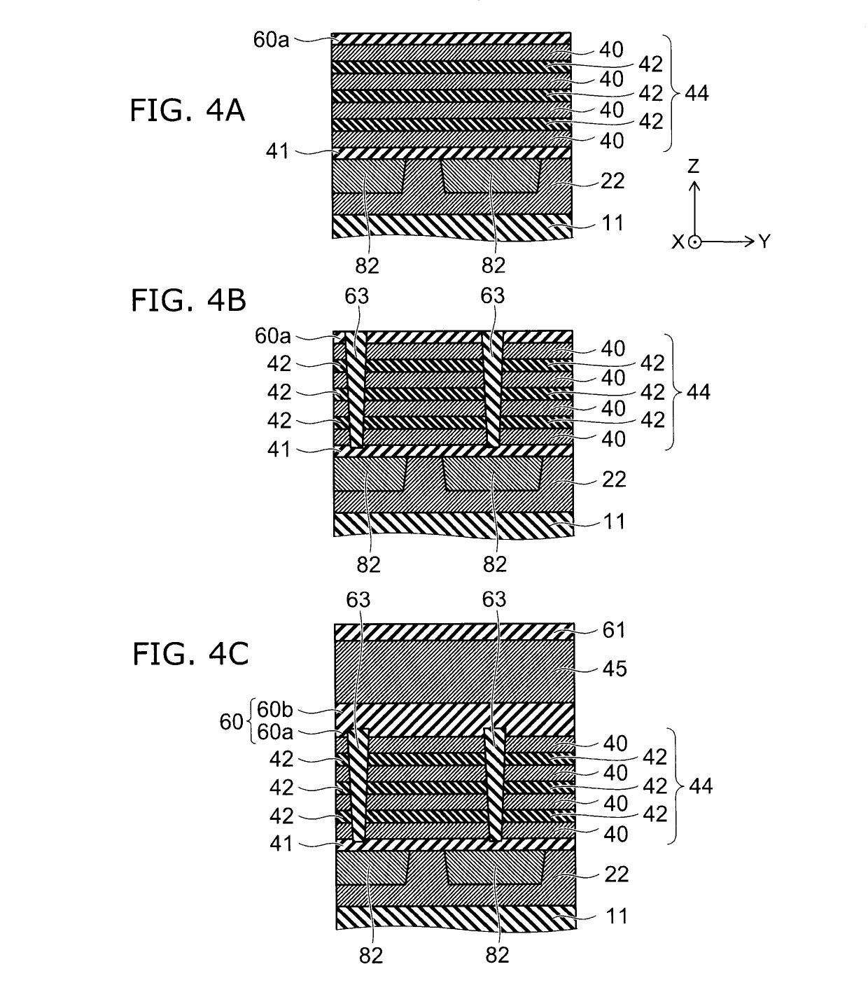

Next, as shown in FIG. 4A, an insulating film 41 is formed on the semiconductor layer 22 and the sacrifice layer 82. Successively, the stacked body 44 is formed on the foundation layer 11, via the insulating film 41. The stacked body 44 is formed by alternate stacking of each of the plurality of electrode layers 40 and each of the plurality of insulating layers 42. Successively, an insulating film 60a is formed on the uppermost electrode layer 40.

Next, by photolithography and RIE (Reactive Ion Etching), the insulating film 60a and the stacked body 44 are segmented in the Y-direction and a trench reaching the insulating film 41 is formed. After that, an insulating film 63 is embedded in this trench. This state is shown in FIG. 4B.

For example, FIG. 4B shows a state where the insulating layer 63 is subjected to etch-back, and the upper end of the insulating layer 63 and the surface of the insulating film 60a are flush with each other. The insulating film 63 extends in the X-direction.

Next, as shown in FIG. 4C, an insulating film 60b is formed on the stacked body 44 via the insulating film 60a. Thereby, the interlayer insulating film 60 including the insulating film 60a and the insulating film 60b is formed on the stacked body 44. Furthermore, the selection gate electrode 45 is formed on the interlayer insulating film 60. Successively, the interlayer insulating film 61 is formed on the selection gate electrode 45.

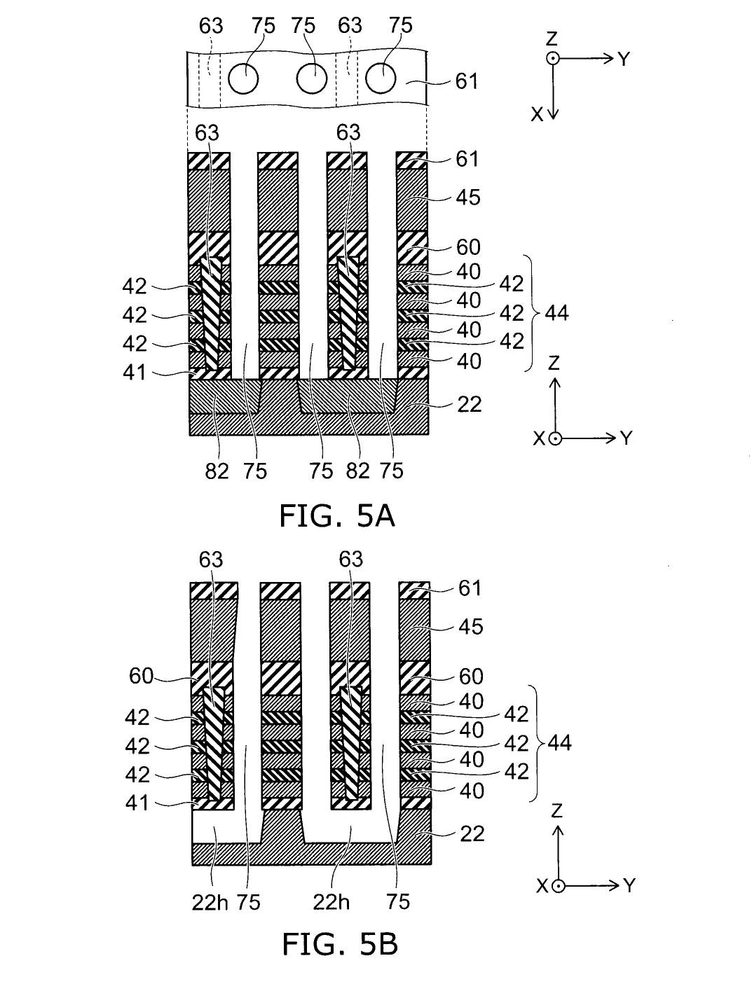

In FIG. 5A and the subsequent drawings, illustration of the foundation layer 11 is omitted.

Next, as shown in FIG. 5A, by photolithography and RIE, the memory hole 75, which is passing through the interlayer insulating film 61, the selection gate electrode 45, the interlayer insulating film 60, and the stacked body 44, is formed. The memory hole 75 extends in the stacking direction of the stacked body 44 (Z-direction). A pair of memory holes 75 is formed on the sacrifice layer 82 so as to sandwich the insulating layer 63 which is positioned at approximately the center of the sacrifice layer 82.

FIG. 5A shows a schematic top view other than a schematic cross-sectional view. The memory hole 75 has a circular outer shape, for example, when cut along the X-direction (or Y-direction). In the step shown in FIG. 5A, the memory hole 75 is formed so as to cause each lower end of the pair of memory holes 75 to reach the sacrifice layer 82. After RIE, the sacrifice layer 82 is exposed at the bottom part of the memory hole 75.

Next, as shown in FIG. 5B, the sacrifice layer 82 is removed through the memory hole 75 by wet etching, for example. For etching solution, there is used alkali-series chemical solution such as KOH (potassium hydrate) or phosphoric acid solution (H₃PO₄) which has an etching rate adjusted according to a temperature condition, for example.

Thereby, the sacrifice layer 82 is removed and the concave part 22h is formed again in the semiconductor layer 22. One pair of memory holes 75 are connected with each other through one concave part 22h. That is, each lower end of the pair of memory holes 75 is connected to one concave part 22h and one U-shaped memory hole 75 is formed. After that, the memory film 30 and the gate insulating film 50 are formed inside the memory hole 75.

A manufacturing process will be described for the memory film 30 and the gate insulating film 50 according to the first embodiment.

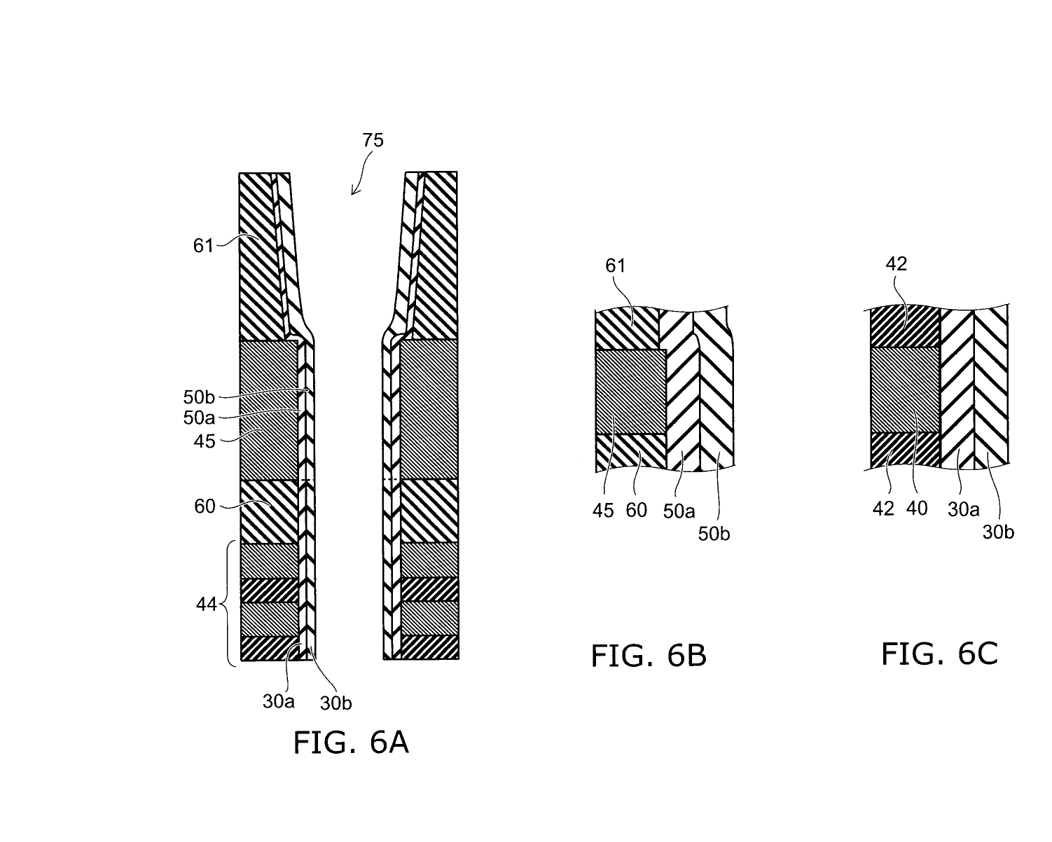

FIGS. 6A to 12C are schematic cross-sectional views describing the manufacturing process for the memory film and the gate insulating film according to the first embodiment.

As shown in FIGS. 6A to 6C, after the memory hole 75 has been formed, hydrofluoric acid treatment is provided for the inside of the memory hole 75, and the step 65 is formed between the selection gate electrode 45 and the interlayer insulating film 61. By this hydrofluoric acid treatment, a natural oxide film, which is formed on each surface of the selection gate electrode 45 and electrode layer 40 exposed on the side of the memory hole 75, is removed.

Successively, the nitride film 30a and the nitride film 50a are formed inside the memory hole 75. The nitride film 30a and the nitride film 50a are formed at the same time. Further, the oxide film 30b is formed on the nitride film 30a and the oxide film 50b is formed on the nitride film 50a. The oxide film 30b and the oxide film 50b are formed at the same time.

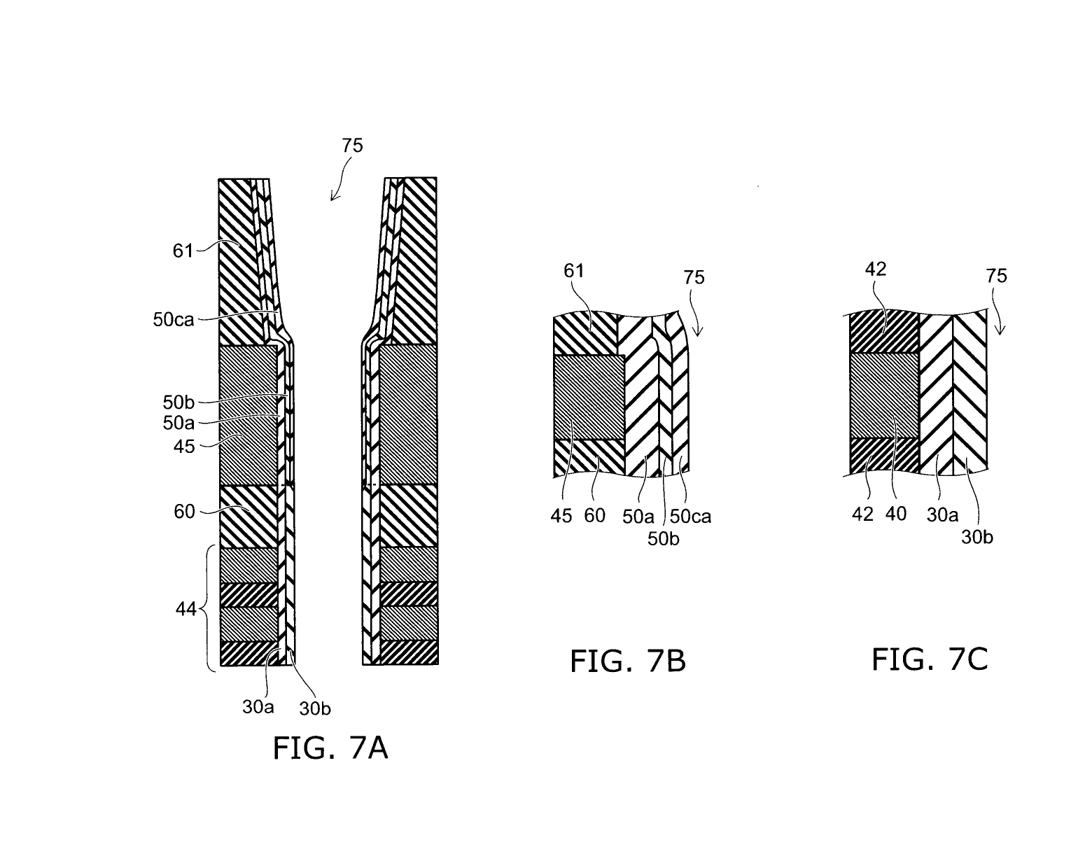

Next, as shown in FIGS. 7A to 7C, at least a part of the oxide film 50b is nitrided, and thereby at least a part of the oxide film 50b is changed into a nitride film 50ca. For example, the surface of the oxide film 50b which is exposed on the side of the memory hole 75 is exposed to plasma including nitrogen (N), and the oxide film 50b is nitrided from the surface to a predetermined depth.

The condition of the nitriding treatment is set to a condition in which the oxide film 50b is exposed to the plasma including nitrogen and the oxide film 30b is not exposed to the plasma including nitrogen. For example, the process is performed without applying a bias to an object to be treated so as to cause the object to be exposed to plasma during the plasma treatment. Thereby, it becomes difficult for active species in the plasma to be pulled down to the lower side from the stacked body 44, in the memory hole 75. Alternatively, plasma gas is set to have a high pressure, and the plasma gas is caused not to reach the lower side from the stacked body 44 in the memory hole 75. That is, the first embodiment selects a condition in which the oxide film 50b is more selectively exposed to the plasma than the oxide film 30b.

Gas used for the nitriding needs not be the plasma and nitrogen gas may be used. For example, at least a part of at least one layer of the oxide films is exposed to gas including nitrogen and is heated, and thereby at least a part of the at least one layer of the oxide films is nitrided. Furthermore, there may be used a method that plasma including nitrogen is sprayed in pulses to an object to be treated from the above.

The part nitrided in the oxide film 50b may be an oxynitride film (SiON) in which oxygen remains.

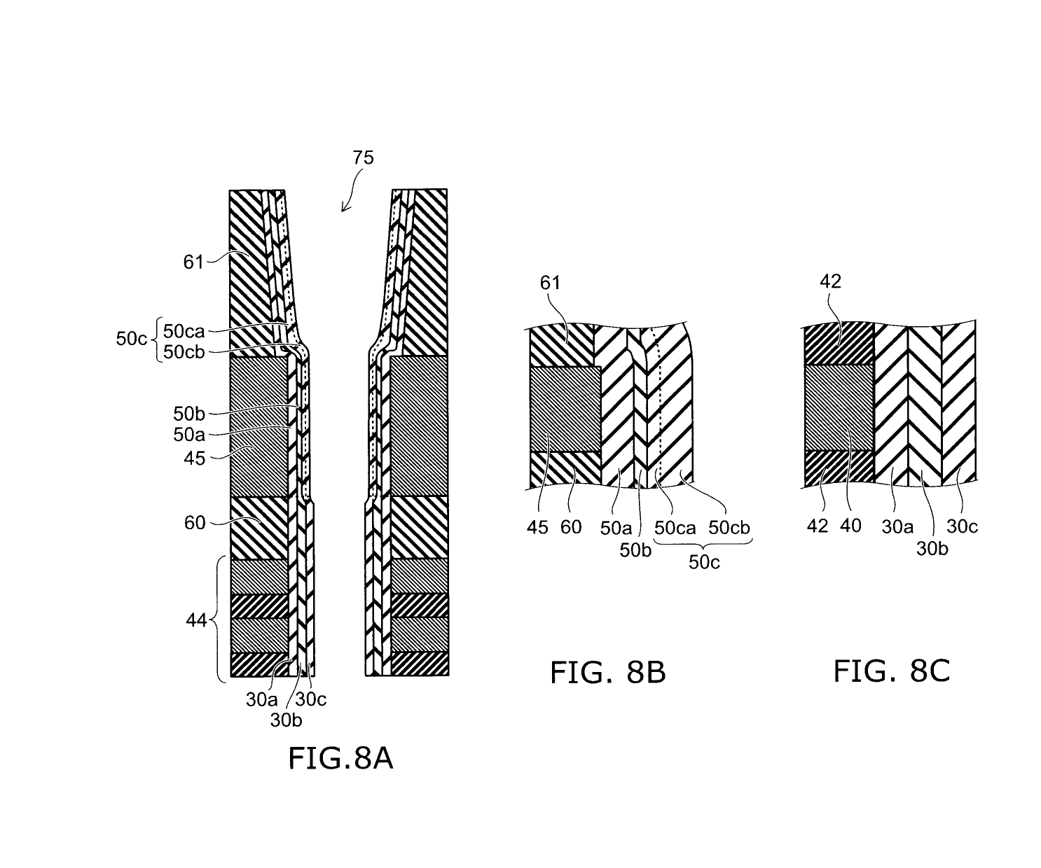

Next, as shown in FIGS. 8A to 8C, the nitride film 30c is formed on the oxide film 30b. Further, a nitride film 50cb is formed on the nitride film 50ca. The nitride film 30c and the nitride film 50cb are formed at the same time. Thereby, the nitride film 50c including the nitride film 50ca and the nitride film 50cb is formed on the oxide film 50b.

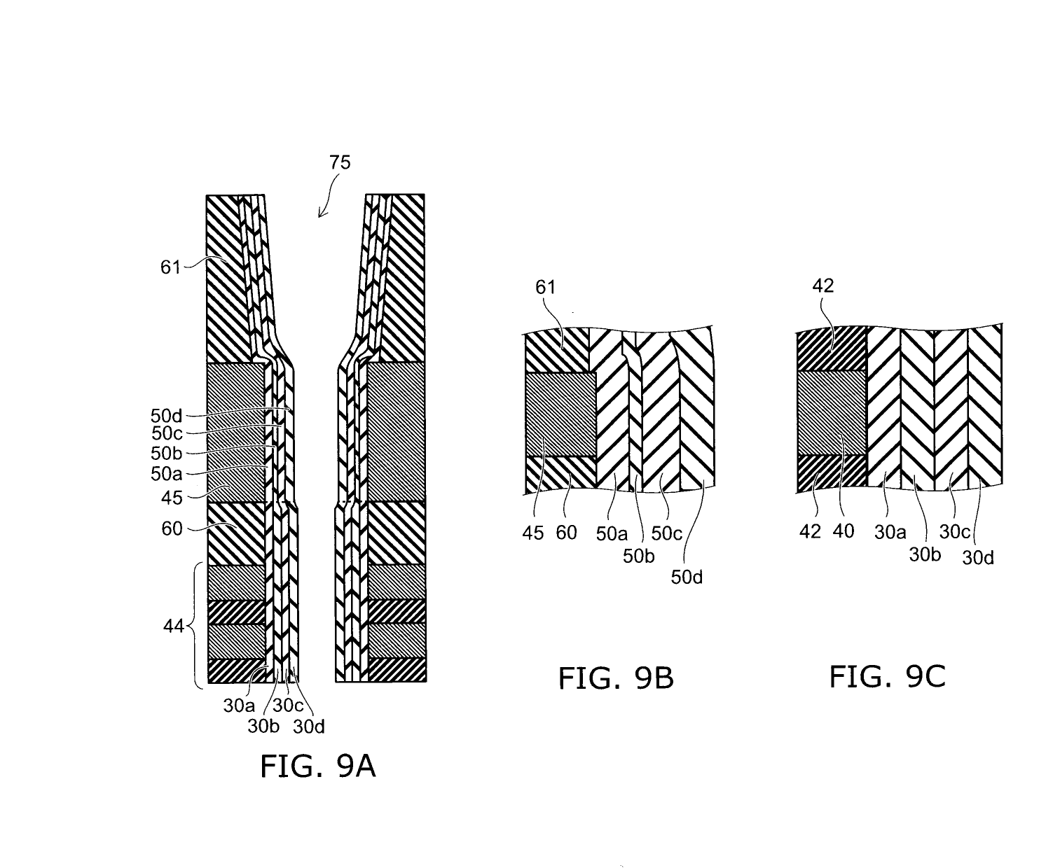

Next, as shown in FIGS. 9A to 9C, the oxide film 30d is formed on the nitride film 30c and the oxide film 50d is formed on the nitride film 50c. The oxide film 30d and the oxide film 50d are formed at the same time.

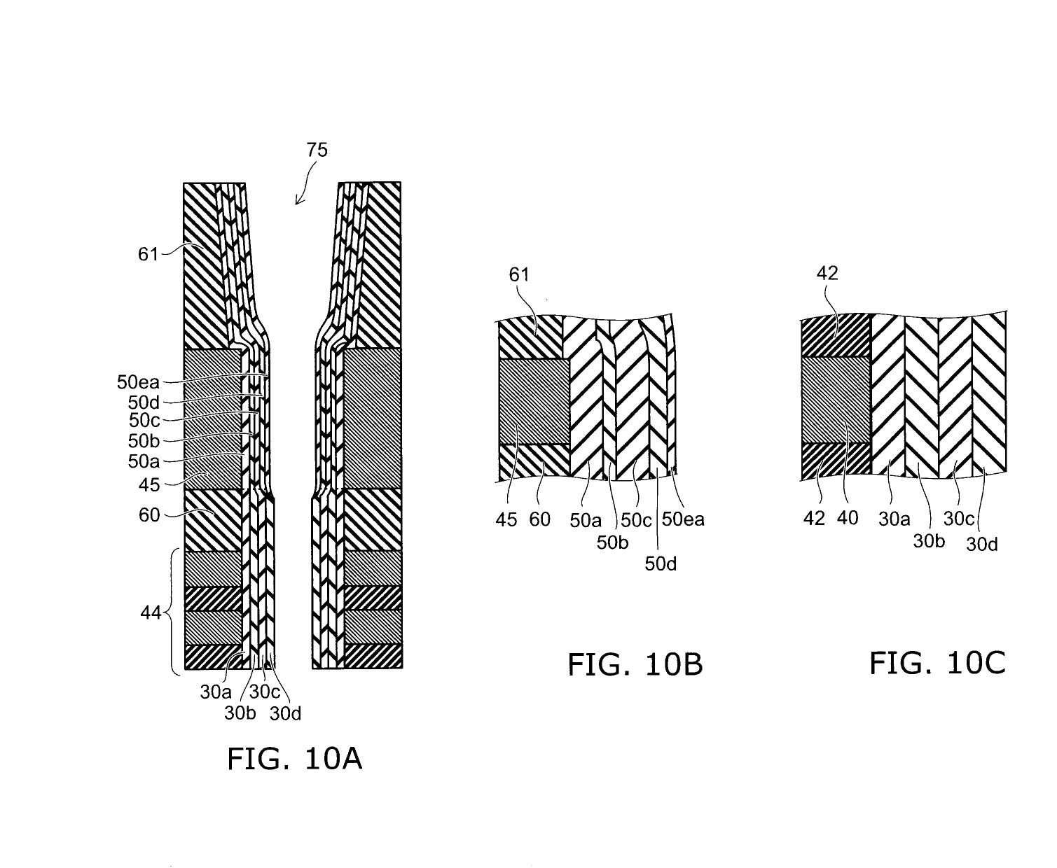

Next, as shown in FIGS. 10A to 10C, by nitriding of at least a part of the oxide film 50d, at least a part of the oxide film 50d is changed into a nitride film 50ea. The formation method of the nitride film 50ea is the same as the formation method of the nitride film 50ca. That is, there is selected a condition in which the oxide film 50d is more selectively nitrided than the oxide film 30d.

The part nitrided in the oxide film 50d may be an oxynitride film (SiON) in which oxygen remains.

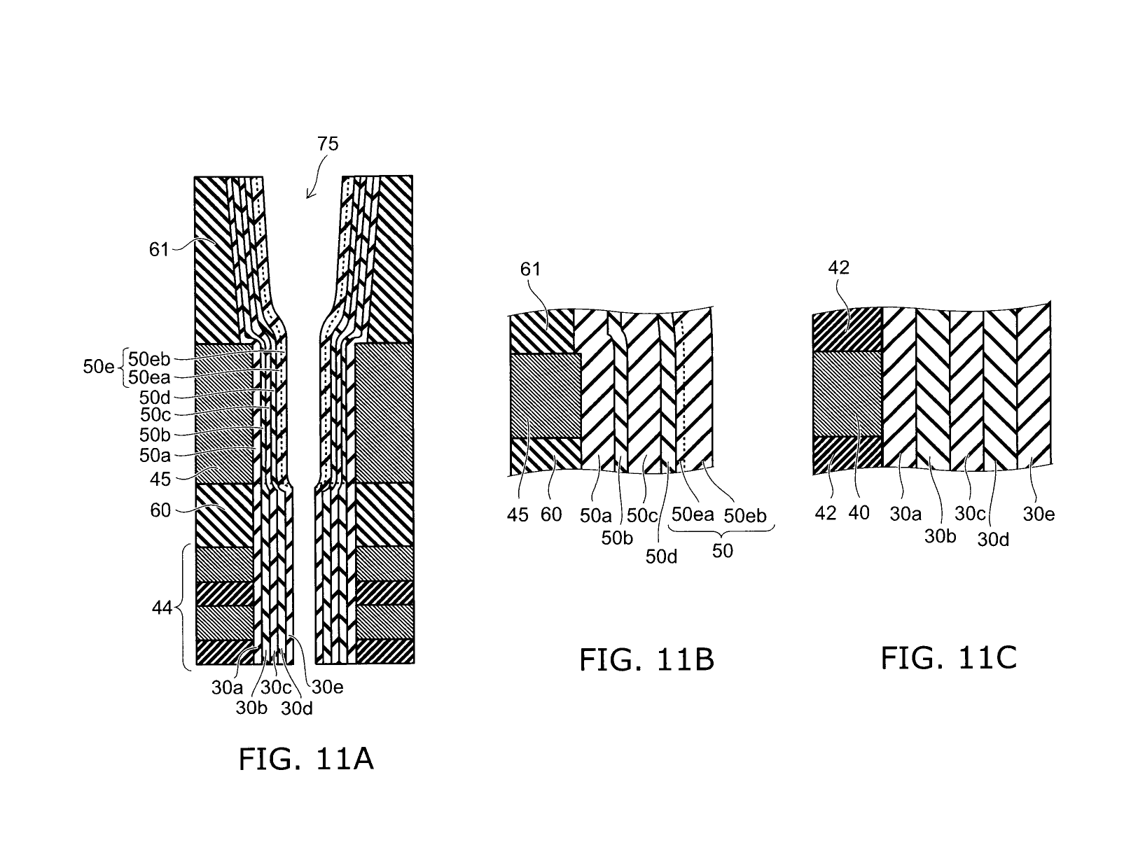

Next, as shown in FIGS. 11A to 11C, the nitride film 30e is formed on the oxide film 30d. Further, a nitride film 50eb is formed on the oxide film 50ea. The nitride film 30e and the nitride film 50eb are formed at the same time. Thereby, the nitride film 50e including the nitride film 50ea and the nitride film 50eb is formed on the oxide film 50d.

After that, as shown in FIG. 2B and FIG. 2C, the oxide film 30f is formed on the nitride film 30e. Furthermore, the oxide film 50f is formed on the nitride film 50e. The oxide film 30f and the nitride film 50f are formed at the same time. In such a process, the memory film 30 and the gate insulating film 50 are formed.

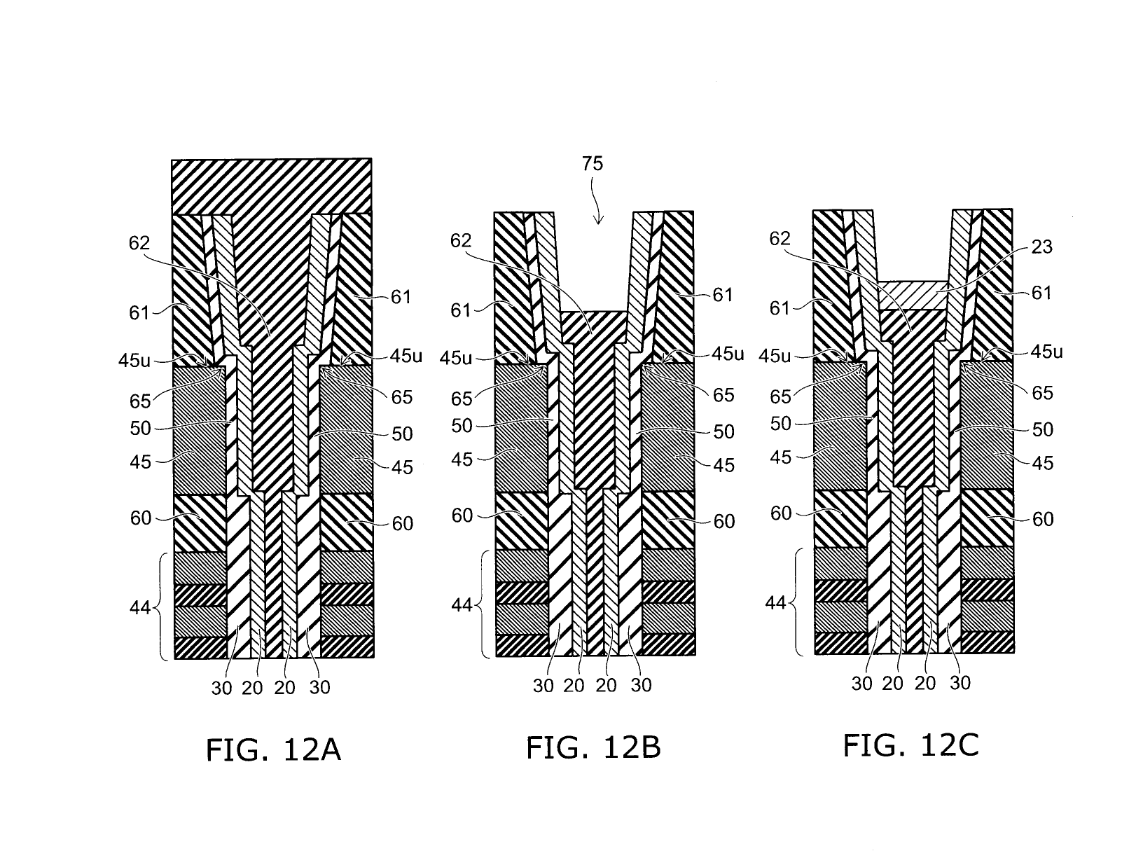

FIGS. 12A to 12C are schematic cross-sectional views explaining a manufacturing process for the nonvolatile semiconductor memory device according to the first embodiment.

Next, as shown in FIG. 12A, the channel body layer 20 and the insulating layer 62 are formed sequentially inside the memory film 30 and the gate insulating film 50.

Successively, as shown in FIG. 12B, the insulating layer 62 is etched back. At this time, the insulating layer 62 is more selectively etched than the channel body layer 20, and thereby the channel body layer 20 is exposed in the upper part of the memory hole 75.

Next, as shown in FIG. 12C, the conductive layer 23 is formed on the channel body layer 20.

After that, as shown in FIG. 2A, the via 49 is formed. Furthermore, as shown in FIG. 1, the source line 47, the bit line 48 and the like are formed. The existence of the conductive layer 23 suppresses the diffusion of an impurity element contained in the via 49 into the lower side from the selection gate electrode 45.

While FIGS. 2A to 2C illustrate total six layers of the insulating films including three layers of the oxide films and three layers of the nitride films (gate insulating film 50 and memory film 30), the number of layers is not always six layers. For the gate insulating film 50, FIGS. 2A to 2C illustrate the case where a part of the surface in each of the first and the second oxide films from the side of the gate electrode 45 is nitrided. As to the nitriding, the whole oxide film may be nitrided.

Furthermore, generally a silicon nitride film has more electrical trap levels than a silicon oxide film. Therefore, the oxide films 30f and 50f are not subjected to the nitriding treatment, and the oxide films 30f and 50f are caused to contact the channel body layer 20.

In this manner, the manufacturing process of the nonvolatile semiconductor memory device 1 according to the first embodiment includes the processing of subjecting the oxide film to the nitriding treatment. When the oxide film is subjected to the nitriding treatment, the film thickness of the oxide film is reduced (to be described below).

In the first embodiment, the film thickness of at least a part of the gate insulating film 50 is made smaller than the film thickness of the memory film 30, by the nitriding. That is, at least a part of the oxide film included in the gate insulating film 50 is changed into a nitride film, and thereby the film thickness of the gate insulating film 50 is made thinner than the film thickness of the memory film 30.

Before the film thickness of at least a part of the gate insulating film 50 is made thinner than the film thickness of the memory film 30, the gate insulating film 50 includes at least one layer of the oxide film. Then, at least a part of the oxide film is nitrided, and thereby the film thickness of at least a part of the gate insulating film 50 is made thinner than the film thickness of the memory film 30. The film thickness may be controlled with the above described equivalent oxide film thickness.

There will be described the reason why the film thickness of the deposited film is reduced when the oxide film is changed into the nitride film.

For example, it is assumed that the molecular weight of silicon oxide (SiO₂) is 60 g, the density is 2.2 g/cm³, the volume per one mole is 27.3 cm³/mol, and the relative permittivity is 3.9.

Further, it is assumed that the molecular weight of silicon nitride (Si₃N₄) is 46.7 g, the density is 2.9 g/cm³, the volume per one mole is 16.1 cm³/mol, and the relative permittivity is 7.4.

When the oxide film is changed into the nitride film, the film thickness of the deposited film becomes a thickness of 0.59 times from a formula of (Silicon nitride volume per mol)/(Silicon oxide volume per mol)=0.59. That is, when the oxide film is changed into the nitride film, the film thickness of the deposited film is reduced by approximately 40%.

Furthermore, in the conversion into the equivalent oxide film thickness, the film thickness of the deposited film becomes a thickness of 0.31 times when the oxide film is changed into the nitride film. Here, the above described formula (I) is used. That is, when the oxide film is changed into the nitride film, the equivalent oxide film thickness of the deposited film is reduced by approximately 70%.

Characteristics of the selection gate electrode 45 depends on a resistance value and the like of the channel body layer 20 in which the channel is formed, or electrical characteristics of the gate insulating film 50 which is sandwiched by the selection gate electrode 45 and the channel body layer 20.

In a MOS transistor, as the equivalent oxide film thickness of a gate insulating film becomes thinner, controllability of a gate electrode becomes better. Here, as one indicator of the gate electrode controllability, there is used a potential necessary for switching between an on-state and an off-state. The on-state is a state in which current flows in the channel and the off-sate is a state in which current does not flow in the channel. The gate electrode controllability is considered to be better when the on-state and the off-state are switched at a lower potential.

There will be described an example of data erasing operation in the nonvolatile semiconductor memory device 1.

In the nonvolatile semiconductor memory device 1, the above described GIDL is utilized when data is erased from the memory cell.

For example, a potential higher than the potential of the selection gate electrode 45 is applied to the source line 47. Thereby, a depletion layer is formed within the channel body layer 20 above the selection gate electrode 45. A strong electric field is applied to the channel body layer 20 in which the depletion layer is formed, and an electron and a hole are generated (generation of an electron-hole pair). Then, the hole is injected into the channel body layer 20 below the selection gate electrode 45. Thereby, in the stacked body 44, the potential of the channel body layer 20 becomes higher than the potential of the electrode layer 40.

In contrast, the electrode layer 40 is set to have a low voltage. Therefore, the electron stored in the nitride film 30c is pulled out by a potential difference between the increased potential of the channel body layer 20 and the potential of the electrode layer 40. Thereby, the data is erased. Alternatively, a hole generated by inter-band tunneling is directly injected into the nitride film 30c, and the data is erased by pair annihilation of a hole and electron.

In the nonvolatile semiconductor memory device 1, the impurity concentration of the channel body layer 20 above the step 65 is set to be higher, and thereby the width of the depletion layer formed in the channel body layer 20 above the step 65 becomes smaller. Therefore, a stronger electric field is applied to the depletion layer, and an electron and a hole are generated efficiently.

In the nonvolatile semiconductor memory device 1, the film thickness (or equivalent oxide film thickness) of the gate insulating film 50 is thinner than the film thickness (or equivalent oxide film thickness) of the memory film 30. Accordingly, the controllability of the selection gate electrode 45 becomes better.

For example, in the nonvolatile semiconductor memory device 1, when GIDL is generated, it is possible to set a voltage between the selection gate electrode 45 and the source line 47 to be lower. When the film thickness (or equivalent oxide film thickness) of the selection gate film is increased, the potential of the selection gate electrode becomes hard to be conducted sufficiently to the channel body layer, via the gate insulating layer. Therefore, when GIDL is generated, it is necessary to set the voltage between the selection gate electrode 45 and the source line 47 to be higher than the voltage in the nonvolatile semiconductor memory device 1.

That is, according to the first embodiment, it is possible to set the voltage for obtaining an appropriate amount of GIDL to be lower. As a result, power consumption is reduced in the whole nonvolatile semiconductor memory device. In addition, since the voltage to be applied across the selection gate electrode 45 and the source line 47 can be reduced, a load of the peripheral circuit is reduced. Thereby, reliability of the peripheral circuit is enhanced.

Furthermore, in the nonvolatile semiconductor memory device 1, it is possible to set the threshold voltage of the selection gate electrode 45 to be lower when sense current (Iₒₙ) is caused to flow (on-time). In addition, it is possible to reliably shut down the sense current (I_{off}) in off-time. Since the threshold voltage of the selection gate electrode 45 is reduced, a load of the peripheral circuit is reduced. Thereby, reliability of the peripheral circuit is enhanced.

Moreover, after the channel body layer 20 has been formed, the hollow part remains in the center part of the memory hole 75. In the nonvolatile semiconductor memory device 1, the gate insulating film 50 is formed to have a film thickness thinner than the film thickness of the memory film 30, and thus a step is caused also in this hollow part. The step in the hollow part is located beside the above described step 65. That is, the diameter R2 of the hollow part at the position of the gate electrode 45 is larger than the diameter R1 of the hollow part at the position of the stacked body 44 (refer to FIG. 2A).

Further, according to the nonvolatile semiconductor memory device 1, the gate insulating film 50 has a multilayer structure, and thereby it is difficult for leak current to flow within the gate insulating film, compared with the gate insulating film of a single layer.

Furthermore, according to the manufacturing method of the nonvolatile semiconductor memory device 1, the thinning processing of the gate insulating film 50 does not require an etching process. That is, the thinning processing of the first embodiment is simple and does not increase manufacturing cost.

### Second Embodiment

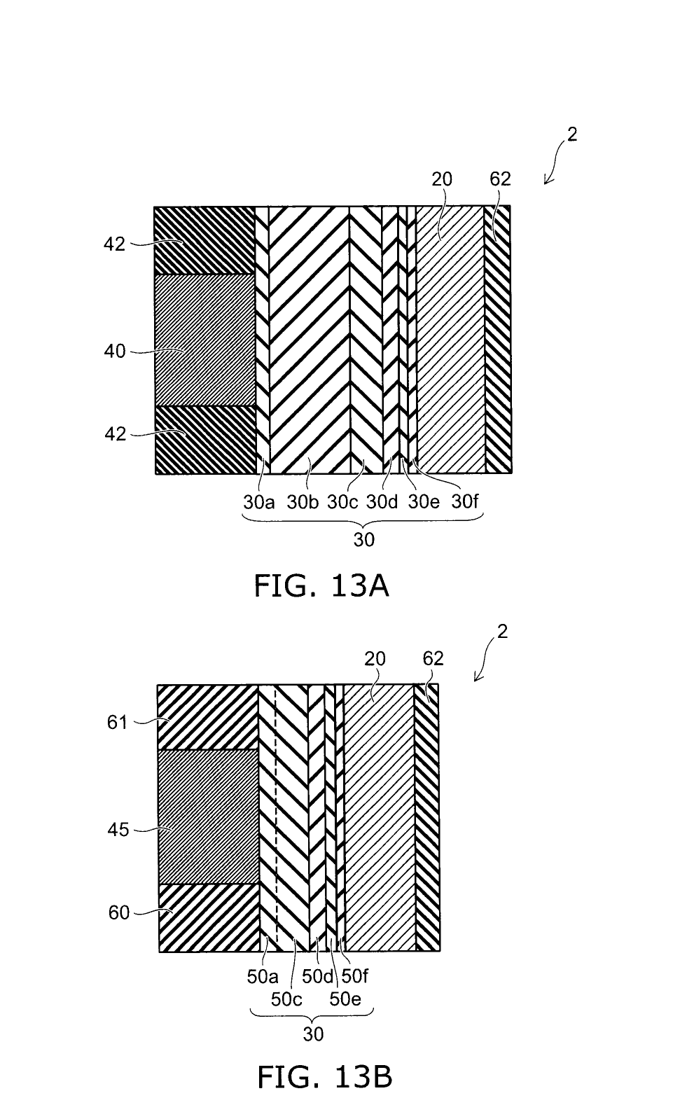

FIGS. 13A and 13B are schematic cross-sectional views of a nonvolatile semiconductor memory device according to a second embodiment, and FIG. 13A is a schematic cross-sectional view in the vicinity of the electrode layer and FIG. 13B is a schematic cross-sectional view in the vicinity of the selection gate.

The film thickness (or equivalent oxide film thickness) of the gate insulating film 50 is thinner than the film thickness (or equivalent oxide film thickness) of the memory film 30 in the nonvolatile semiconductor memory device 2 according to the second embodiment. The memory film 30 of the nonvolatile semiconductor memory device 2 has the same structure as the structure shown in FIG. 2C. The gate insulating film 50 of the nonvolatile semiconductor memory device 2 includes at least one layer of the oxide film. The number of layers for the oxide films included in the gate insulating film 50 is smaller than the number of layers for the oxide films included in the memory film 30. For example, while the number of layers for the oxide films included in the gate insulating film 50 is two of the oxide films 50d and 50f, the number of layers for the oxide films included in the memory film 30 is three of the oxide films 30b, 30d, and 30f.

Before at least a part of the gate insulating film 50 according to the second embodiment is made thinner than the film thickness of the memory film 30, the gate insulating film 50 includes at least one layer of the oxide film. In the second embodiment, at least a part of at least one layer of the oxide film included in the gate insulating film 50 is removed before thinning, and thereby the film thickness of at least a part of the gate insulating film 50 is made thinner than the film thickness of the memory film.

For example, at least a part of at least one layer of the oxide film is exposed to gas containing fluorine, and thereby at least a part of at least one layer of the oxide film is removed. FIG. 13B shows a state in which the above described oxide film 50b is once formed as shown in FIG. 6A and then the removal of the whole oxide film 50b causes the process to proceed.

Also in this case, the condition is set in which the oxide film 50b is exposed to the gas containing fluorine and the oxide film 30b is not exposed to the gas containing fluorine. For example, one of pressure and temperature of the gas containing fluorine is set to be high, or the pressure and the temperature are set to be high, and thus the gas containing fluorine is not caused to reach the lower part from the stacked body 44 in the memory hole 75. When the pressure is increased, it becomes difficult for the gas containing fluorine to reach the lower side in the memory hole 75, that is, the stacked body 44. Furthermore, when the temperature is increased, the gas containing fluorine is preferentially consumed for reaction in the vicinity of the oxide film 50b and becomes difficult to reach the lower side in the memory hole 75, that is, the stacked body 44. That is, in the second embodiment, there is selected a condition in which the oxide film 50b is more selectively exposed to the gas containing fluorine than the oxide film 30b.

Not being limited to the oxide film, at least a part of the nitride film may be removed. In addition, at least a part of one of the oxide film and the nitride film may be removed. By such a method, it is possible to make the film thickness (or equivalent oxide film thickness) of the gate insulating film 50 thinner than the film thickness (or equivalent oxide film thickness) of the memory film 30.

### Third Embodiment

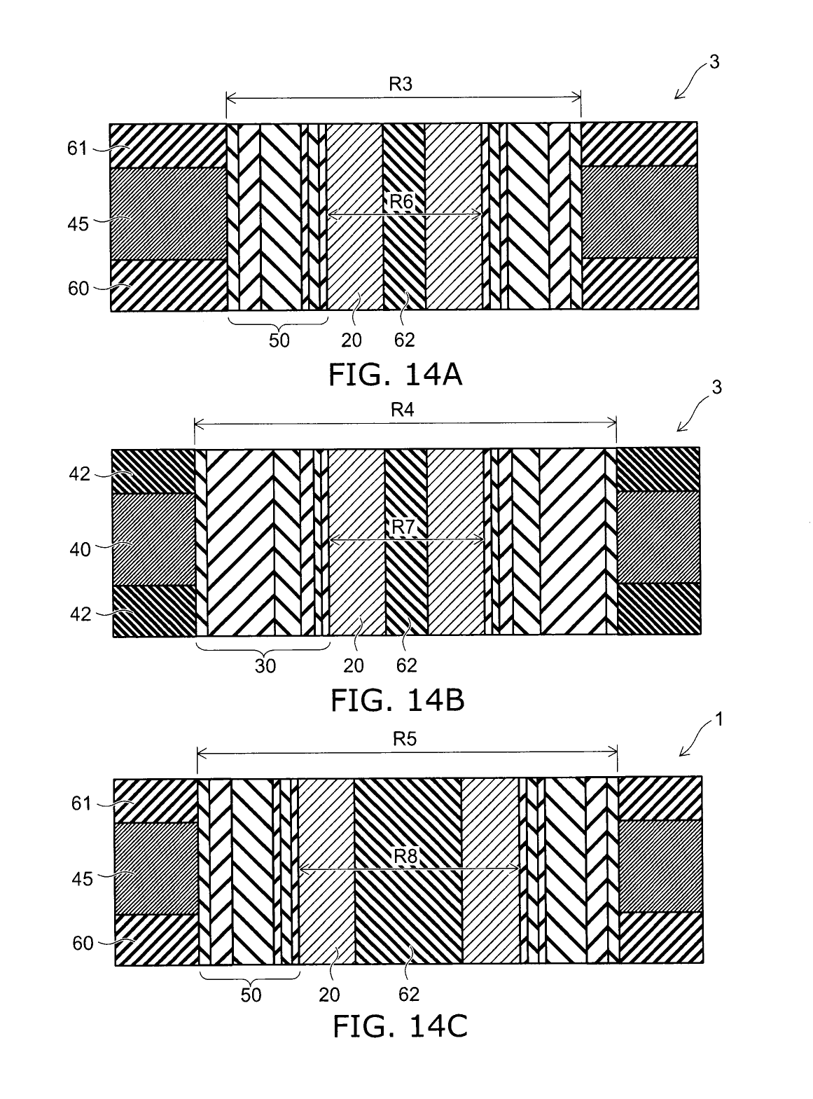

FIG. 14A is a schematic cross-sectional view in the vicinity of the selection gate electrode in a nonvolatile semiconductor memory device according to a third embodiment, FIG. 14B is a schematic cross-sectional view in the vicinity of the electrode layer in the nonvolatile semiconductor memory device according to the third embodiment, and FIG. 14C is a schematic cross-sectional view in the vicinity of the selection gate electrode in the nonvolatile semiconductor memory device according to the first embodiment.

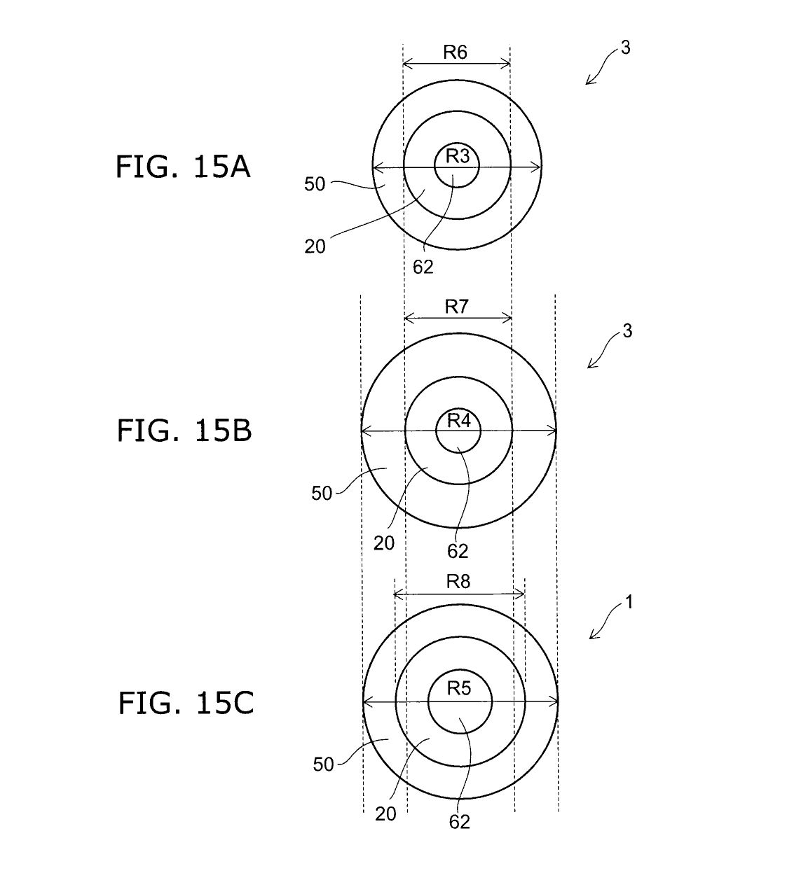

FIG. 15A is a schematic plan view in the vicinity of the selection gate electrode in the nonvolatile semiconductor memory device according to a third embodiment, FIG. 15B is a schematic plan view in the vicinity of the electrode layer in the nonvolatile semiconductor memory device according to the third embodiment, and FIG. 15C is a schematic plan view in the vicinity of the selection gate electrode in the nonvolatile semiconductor memory device according to the first embodiment.

FIG. 15A and FIG. 15C show cross-sections when the gate insulating film 50, the channel body layer 20, and the insulating layer 62 are cut perpendicularly to the stacking direction of the stacked body 44 at the position of the gate electrode 45. FIG. 15B shows a cross-section when the memory film 30, the channel body layer 20, and the insulating layer 62 are cut perpendicularly to the stacking direction of the stacked body 44 at the position of the electrode layer 40.

For example, when the film thickness of the gate insulating film 50 is reduced as in the case of the nonvolatile semiconductor memory device 1 shown in FIG. 14C and FIG. 15C, the outer diameter (R8) of the channel body layer 20 is increased compared with the case without reducing the film thickness of the gate insulating film 50. This is because, in the first embodiment, the memory hole 75 is formed so as to cause the selection gate electrode 45 to have an inner diameter (R5) approximately the same as the inner diameter of the electrode layer 40. Thereby, in the first embodiment, the curvature (½R8) of the channel body layer 20 tends to decrease.

In such a case, when a predetermined potential is applied to the selection gate electrode 45, the electric field density in the channel body layer 20 may be reduced. Therefore, the threshold voltage may be increased and the controllability of the selection gate electrode 45 may not be enhanced. That is, the reduction in the gate insulating film thickness and the curvature increase in the channel body layer have a trade-off relationship therebetween.

In contrast to this, in the nonvolatile semiconductor memory device 3 shown in FIG. 14A, FIG. 14B, FIG. 15A, and FIG. 15B, the inner diameter (R3) of the selection gate electrode 45 when the selection gate electrode 45 is cut perpendicularly to the stacking direction of the stacked body 44 is made smaller than the inner diameter (R4) of the electrode layer 40 when the electrode layer 40 is cut perpendicularly to the stacking direction of the stacked body 44. In other words, the outer diameter (R3) of the gate insulating film 50 is made smaller than the outer diameter (R4) of the memory film 30.

Such a structure suppresses the increase in the outer diameter (R8) of the channel body layer 20 at the position of the selection gate electrode 45. Thereby, when the predetermined potential is applied to the selection gate electrode 45, the electric field in the channel body layer 20 is not reduced, and the threshold voltage is not increased. That is, the controllability of the selection gate electrode 45 is further enhanced.

Such a structure can be formed by a method to be described next.

For example, in the process forming the memory hole 75 (refer to FIG. 5A), the inner diameter (R3) of the memory hole 75 when the memory hole 75 is cut perpendicularly to the stacking direction of the stacked body 44 at the position of the selection gate electrode 45 is made smaller than the inner diameter (R4) of the memory hole 75 when the memory hole 75 is cut perpendicularly to the stacking direction of the stacked body 44 at the position of the electrode layer 40. That is, the inner diameter (R3) of the selection gate electrode after the memory hole 75 has been formed is adjusted so as to become smaller than the inner diameter (R4) of the electrode layer 40 after the memory hole 75 has been formed.

The material for each of the selection gate electrode 45 and the material for each of the plurality of electrode layers 40 are silicon containing an impurity such as boron (B). Here, the concentration of the impurity element contained in the selection gate electrode 45 is set to be higher than the concentration of the impurity contained in each of the plurality of electrode layers 40.

In the etching, there is used, for example, trimethyl-2 hydroxyethylammoniumhydroxide (TMY: ((CH₃)₃NCH₂CH₂OH)+OH⁻) as chemical solution which can provide a selection ratio between non-doped silicon and boron-doped silicon.

When the memory hole 75 is formed through the use of this chemical solution, the etching rate of the selection gate electrode 45 becomes lower than the etching rate of the electrode layer 40, and thereby the inner diameter (R3) of the selection gate electrode becomes smaller than the inner diameter (R4) of the electrode layer 40 after the etching.

It is possible to further reduce the inner diameter (R3) of the selection gate electrode 45 and to further reduce the outer diameter (R6) of the channel body layer 20 at the position of the selection gate electrode 45. For example, the outer diameter (R6) of the channel body layer 20 at the position of the selection gate electrode 45 is made smaller than the outer diameter (R7) of the channel body layer 20 at the position of the electrode layer 40. Thereby, the above described electric field concentration becomes more strong. For example, the structure in which the outer diameter of the channel body layer 20 at the position of the selection gate electrode 45 is smaller than the outer diameter of the channel body layer 20 at the position of the electrode layer 40 is also included in the embodiment.

In the above description, the gate insulating film is an object for an insulating film to be subjected to the thinning processing. When some of the electrode layers 40 below the gate electrode 45 are used as dummy electrodes, the insulating film formed on the side wall of these dummy electrodes may be subjected to the same thinning processing.

Furthermore, there may be prepared the stacked body 44 using a sacrifice layer in stead of the insulating layer 42, and, after the memory hole 75 has been formed, the nonvolatile semiconductor memory device may be formed by a replacement method of removing, at the same time, the sacrifice layer 82 and the sacrifice layer which is sandwiched by the electrode layer 40 and the electrode layer 40. In this case, instead of the insulating film 42, the memory film 30 is provided between the electrode layer 40 and the electrode layer 40.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device, comprising:
a foundation layer;
a stacked body provided on the foundation layer, each of a plurality of electrode layers and each of a plurality of insulating layers being stacked alternately in the stacked body;
an interlayer insulating film provided on the stacked body;
a gate electrode provided on the interlayer insulating film;
a semiconductor layer extending from an upper end of the gate electrode to a lower face of the stacked body;
a first insulating film provided between the semiconductor layer and each of the plurality of electrode layers, and the first insulating film including at least one layer of a nitride film; and
a second insulating film provided between the gate electrode and the semiconductor layer, and the second insulating film including at least one layer of a nitride film,
a film thickness of at least a part of the second insulating film being thinner than a film thickness of the first insulating film.

2. The device according to claim 1, wherein:
the film thickness of the first insulating film is an equivalent oxide film thickness of the first insulating film, and
the film thickness of the second insulating film is an equivalent oxide film thickness of the second insulating film.

3. The device according to claim 1, wherein a film thickness of the at least one layer of a nitride film included in the second insulating film is thicker than a film thickness of the at least one layer of a nitride film included in the first insulating film.

4. The device according to claim 1, wherein:
the first insulating film further includes at least one layer of an oxide film,
the second insulating film further includes at least one layer of an oxide film, and
a number of layers of the oxide films included in the second insulating film is smaller than a number of layers of the oxide films included in the first insulating film.

5. The device according to claim 1, wherein an inner diameter of the gate electrode is smaller than an inner diameter of the electrode layer.

6. The device according to claim 1, wherein,
an outer diameter of the semiconductor layer at a position of the gate electrode is smaller than an outer diameter of the semiconductor layer at each position of the plurality of electrode layers.

7. The device according to claim 1, wherein:
each of the gate electrode and the plurality of electrode layers include semiconductors,
a concentration of an impurity element included in the gate electrode is higher than a concentration of an impurity element included in each of the plurality of electrode layers.

8. A method for manufacturing a nonvolatile semiconductor memory device, comprising:
forming a stacked body on a foundation layer, and each of a plurality of electrode layers and each of a plurality of first insulating layers being stacked alternately in the stacked body;
forming an interlayer insulating film on the stacked body;
forming a gate electrode on the interlayer insulating film;
forming a hole passing through the gate electrode, the interlayer insulating film, and the stacked body;
forming a second insulating layer on a side wall of the hole; and
forming a semiconductor layer on the second insulating film,
the second insulating layer including a first insulating film formed between the semiconductor layer and each of the plurality of electrode layers and a second insulating film formed between the gate electrode and the semiconductor layer, and
a film thickness of at least a part of the second insulating film being made thinner than a film thickness of the first insulating film before the semiconductor layer being formed.

9. The method according to claim 8, wherein:
the film thickness of the first insulating film is an equivalent oxide film thickness of the first insulating film, and
the film thickness of the second insulating film is an equivalent oxide film thickness of the second insulating film.

10. The method according to claim 8, wherein:
the second insulating film includes at least one layer of an oxide film, before the film thickness of at least a part of the second insulating film is made thinner than the film thickness of the first insulating film, and
the film thickness of at least a part of the second insulating film is made thinner than the film thickness of the first insulating film by nitriding of at least a part of the at least one layer of an oxide film.

11. The method according to claim 10, wherein at least a part of the at least one layer of an oxide film is nitrided by using plasma including nitrogen.

12. The method according to claim 10, wherein at least a part of the at least one layer of an oxide film is exposed to gas including nitrogen and is heated to nitride at least a part of the at least one layer of an oxide film.

13. The method according to claim 8, wherein:
the second insulating film includes at least one layer of an oxide film, before the film thickness of at least a part of the second insulating film is made thinner than the film thickness of the first insulating film, and
the film thickness of at least a part of the second insulating film is made thinner than the film thickness of the first insulating film by removing at least a part of the at least one layer of an oxide film.

14. The method according to claim 13, wherein at least a part of the at least one layer of an oxide film is exposed to gas including fluorine to remove at least a part of the at least one layer of an oxide film.

15. The method according to claim 8, wherein:
each of the gate electrode and the plurality of electrode layers include semiconductors,
a concentration of an impurity element included in the gate electrode is higher than a concentration of an impurity element included in each of the plurality of electrode layers.

16. The method according to claim 8, wherein the forming a hole includes a process, and an inner diameter of the gate electrode.
